(19) United States
(12) Patent Application Publication
(10) Pub. No.: US 2015/0022985 A1
(43) Pub. Date: Jan. 22, 2015

(54) DEVICE-EMBEDDED PACKAGE SUBSTRATE AND SEMICONDUCTOR PACKAGE INCLUDING THE SAME

(71) Applicants: KYUNG-TAE NA, Hwaseong-si (KR); CHUL-WOO KIM, Incheon (KR); BOK-SIK MYUNG, Seongnam-si (KR); SEUNG-HWAN LEE, Hwaseong-si (KR)

(72) Inventors: KYUNG-TAE NA, Hwaseong-si (KR); CHUL-WOO KIM, Incheon (KR); BOK-SIK MYUNG, Seongnam-si (KR); SEUNG-HWAN LEE, Hwaseong-si (KR)

(21) Appl. No.: 14/331,419

(22) Filed: Jul. 15, 2014

(30) Foreign Application Priority Data
Jul. 17, 2013 (KR) 10-2013-0084233

(51) Int. Cl. H05K 1/18; H05K 1/02; H05K 1/11

(52) U.S. Cl. CPC H05K 1/183; H05K 1/112; H05K 1/0298; H05K 2201/10015; H05K 2201/10022; H05K 2201/1003
USPC 361/763; 361/761; 361/764

(57) ABSTRACT

A package substrate includes a core layer having a core top surface and a core bottom surface, and a build-up layer having a stacked structure in which a plurality of interconnection layers and a plurality of insulating layers are alternately stacked on the core top surface. The core bottom surface includes a board connecting area. A surface of the build-up layer includes a chip mounting area. The core layer includes at least one cavity defined by recess sidewalls extending upward from the core bottom surface and a recessed surface located at a higher level than or the same level as the core top surface, at least one device mounted in the at least one cavity, and through-electrodes electrically connecting the core top surface and the core bottom surface.

### CROSS-REFERENCE TO RELATED APPLICATIONS

This application claims priority under 35 U.S.C. §119(a) from Korean Patent Application No. 10-2013-0084233 filed on Jul. 17, 2013 in the Korean Intellectual Property Office, the disclosure of which is hereby incorporated by reference in its entirety.

### BACKGROUND

1. Field

The present general inventive concept relates to a device-embedded package substrate, a semiconductor package having the same, a stacked semiconductor package, and an electronic system including the package substrate.

2. Description of the Related Art

Due to light, thin, short, and small features of electronic systems, technologies of integrating a variety of components in a single module, or embedding passive devices, such as a resistor R, a capacitor C, and an inductor I, into a multi-layered printed circuit board in order to increase mounting density, as well as independently making each component smaller and lighter, have been widely studied.

### SUMMARY

The present general inventive concept provides a device-embedded package substrate capable of securing electrical properties of a package and suppressing warpage of the package substrate.

Additional features and utilities of the present general inventive concept will be set forth in part in the description which follows and, in part, will be obvious from the description, or may be learned by practice of the present general inventive concept.

The present general inventive concept also provides a semiconductor package including a device-embedded package substrate capable of securing electrical properties of a package and suppressing warpage of the package substrate.

The present general inventive concept further provides a stacked semiconductor package including a device-embedded package substrate capable of securing electrical properties of a package and suppressing warpage of the package substrate.

The foregoing and/or other features and utilities of the present general inventive concept are achieved by providing a package substrate that includes a core layer having a core top surface and a core bottom surface, and a build-up layer having a stacked structure in which a plurality of interconnection layers and a plurality of insulating layers are alternately stacked on the core top surface and including a chip mounting area on a surface thereof. The core bottom surface includes a board connecting area. The core layer includes at least one cavity, at least one device mounted in the at least one cavity, and through-electrodes electrically connecting the core top surface and the core bottom surface. The at least one cavity is defined by recess sidewalls extending upward from the core bottom surface, and a recessed surface located at a higher level than or the same level as the core top surface.

The at least one device may be formed thicker than the core layer.

A bottom surface of the at least one device may be located at a lower level than, or at the same level as a bottom surface of the package substrate.

A bottom surface of the at least one device may be located at a higher level than the core bottom surface.

The package substrate may further include device connecting terminals located on a top surface of the at least one device and formed from the plurality of interconnection layers.

The at least one cavity may be formed at or near an opposite side to the chip mounting area.

Two or more devices may be mounted in a single cavity, or each device may be mounted in a different cavity.

The core layer may include a material having a lower thermal expansion coefficient and a higher elastic coefficient than the plurality of insulating layers.

The device may be a passive device, such as a capacitor, an inductor, or a resistor.

The foregoing and/or other features and utilities of the present general inventive concept may also be achieved by providing a semiconductor package that includes a package substrate including a core layer having a core top surface and a core bottom surface which has a board connecting area, a build-up layer having a stacked structure in which a plurality of interconnection layers and a plurality of insulating layers are alternately stacked on the core top surface and including a chip mounting area on a surface thereof, at least one cavity defined by recess sidewalls extending upward from the core bottom surface and a recessed surface located at a higher level than or the same level as the core top surface, at least one device mounted in the at least one cavity, and through-electrodes electrically connecting the core top surface and the core bottom surface, at least one semiconductor chip mounted on the chip mounting area, and board connectors formed on the board connecting area and electrically connecting the package substrate to an external board.

A bottom surface of the at least one device may be located at a lower level than a bottom surface of the package substrate, and the difference between the bottom surface of the device and the bottom surface of the package substrate may be smaller than or the same as a joint gap size between the package substrate and the external board.

The board connectors may be formed on the core bottom surface excluding the devices.

The foregoing and/or other features and utilities of the present general inventive concept may also be achieved by providing a stacked semiconductor package that includes a lower semiconductor package including a lower package substrate and at least one lower semiconductor chip, an upper semiconductor package including an upper package substrate and at least one upper semiconductor chip mounted on the upper semiconductor package substrate, inter-package connectors connecting the lower package substrate and the upper package substrate, and board connectors formed on the board connecting area of the lower semiconductor package. The lower package substrate includes a lower core layer having a core top surface and a core bottom surface which includes a board connecting area, a build-up layer having a stacked structure in which a plurality of interconnection layers and a plurality of insulating layers are alternately stacked on the core top surface and including a chip mounting area on a surface thereof, at least one cavity defined by recess sidewalls extending upward from the core bottom surface and a recessed surface located at a higher level than or the same level as the core top surface, at least one device mounted in the at least one cavity, and through-electrodes electrically connecting the core top surface and the core bottom surface. The at least one lower semiconductor chip is mounted on the chip mounting area of the lower package substrate.

The foregoing and/or other features and utilities of the present general inventive concept may also be achieved by providing a semiconductor package substrate including a core layer having a top surface and a bottom surface, a build-up layer, disposed on the top surface of the core layer, having interconnection layers connected through vias, a cavity penetrating from the bottom surface through the top surface of the core layer and recessed within a bottom surface of the build-up layer to house a device thicker than the core layer therein, connecting terminals disposed outside of the cavity at the bottom surface of the core layer to connect the device to an external component.

The build-up layer having the interconnection layers may also include a plurality of insulation layers each alternately stacked with each of the interconnection layers.

The cavity may be defined by recessed walls extending upward from the bottom surface of the core layer and a recessed surface located at a level higher than or the same as the top surface of the core layer.

In the semiconductor package substrate, a top surface of the build-up layer may include a chip-mounting area.

The bottom surface of the core layer may include a board connecting area at the bottom surface of the core layer to connect with the external component.

The core layer and the build-up layer may be connected by through-electrodes.

The cavity may be mounted with multiple devices.

The semiconductor package substrate may have multiple cavities.

In the semiconductor package substrate, a bottom surface of the device may be protruding out from a level corresponding to the bottom surface of the core layer.

A top surface of the device may be protruding out from a level corresponding to the top surface of the core layer.

The device may be electrically connected to the build-up layer through at least one of the interconnection layers and the vias.

The foregoing and/or other features and utilities of the present general inventive concept may also be achieved by providing a semiconductor package substrate comprising a core layer including an uneven top surface and a discontinuous bottom surface to form a cavity within the core layer to house a device therein such that the device has a thickness greater than a thickness of the core layer, a build-up layer disposed on the top surface of the core layer and including a plurality of interconnection layers connected by vias on the top surface of the core layer, and connecting terminals located at the bottom surface of the core layer outside a region where the cavity is formed to allow the device to connect with an external component through the connecting terminals.

The foregoing and/or other features and utilities of the present general inventive concept may also be achieved by providing a semiconductor package substrate comprising a build-up layer having a stacked structure and a chip mounting area on a top surface thereof, a core layer including a top surface to contact a bottom surface of the build-up layer, and a cavity formed within a portion of the core layer including sidewalls extending from a bottom surface of the core layer past the top surface of the core layer to house therein a device having a thickness greater than a thickness of the core layer.

### BRIEF DESCRIPTION OF THE DRAWINGS

The above and/or other features and utilities of the present general inventive concept will become apparent and more readily appreciated from the following description of the embodiments, taken in conjunction with the accompanying drawings of which:

FIGS. 1A and 1B are cross-sectional views illustrating a package substrate in accordance with an exemplary embodiment of the present general inventive concept;

FIG. 2 is a cross-sectional view illustrating the package substrate in accordance with an exemplary embodiment of the present general inventive concept;

FIG. 3 is a cross-sectional view illustrating the package substrate in accordance with an exemplary embodiment of the present general inventive concept;

FIGS. 4A and 4B are cross-sectional views illustrating the package substrate in accordance with exemplary embodiments of the present general inventive concept;

FIGS. 5A and 5B are cross-sectional views illustrating the package substrate in accordance with exemplary embodiments of the present general inventive concept;

FIGS. 6A and 6B are cross-sectional views illustrating the package substrate in accordance with exemplary embodiments of the present general inventive concept;

FIGS. 7A through 7H are cross-sectional views illustrating semiconductor packages in accordance with various exemplary embodiments of the present general inventive concept;

FIGS. 8A through 8F are cross-sectional views illustrating stacked semiconductor packages in accordance with various exemplary embodiments of the present general inventive concept;

FIG. 9 is a module in accordance with an exemplary embodiment of the present general inventive concept;

FIG. 10 is a block diagram schematically illustrating an electronic system in accordance with an exemplary embodiment of the present general inventive concept;

FIG. 11 is a block diagram schematically illustrating an electronic system including a module in accordance with an exemplary embodiment of the present general inventive concept; and

FIG. 12 illustrates a mobile phone including a semiconductor package in accordance with an exemplary embodiment of the present general inventive concept.

### DETAILED DESCRIPTION OF THE EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

The terminology used herein to describe exemplary embodiments of the present general inventive concept is not intended to limit the scope of the present general inventive concept. The articles “a” and “an” are singular in that they have a single referent, however the use of the singular form in the present document should not preclude the presence of more than one referent. In other words, elements referred to in the singular may number one or more, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Terms such as “beneath,” “below,” “lower,” “above,” “upper” and the like may be used herein to describe the relationship of one element or feature to another, as illustrated in the drawings. It will be understood that such descriptions are intended to encompass different orientations in use or operation in addition to orientations depicted in the drawings. For example, if a device is turned over, elements described as “below” or “beneath” other elements or features would then be oriented “above” the other elements or features. Thus, the term “below” is intended to mean both above and below, depending upon overall device orientation. In addition, the device may reoriented in other ways (rotated 90 degrees or at other orientations) and the descriptors used herein should be interpreted accordingly.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. Other words used to describe relationships between elements should be interpreted in a like fashion (i.e., “between” versus “directly between,” “adjacent” versus “directly adjacent,” etc.).

It will be understood that, although the terms first, second, A, B, etc. may be used herein in reference to elements of the present general inventive concept, such elements should not be construed as limited by these terms. For example, a first element could be termed a second element, and a second element could be termed a first element, without departing from the scope of the present general inventive concept. Herein, the term “and/or” includes any and all combinations of one or more referents.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted into non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device, or to limit the scope of the present general inventive concept.

Unless otherwise defined, all terms (including technical and scientific terms) used herein are to be interpreted as is customary in the art to which the present general inventive concept belongs. It will be further understood that terms in common usage should also be interpreted as is customary in the relevant art and not in an idealized or overly formal sense unless expressly so defined herein.

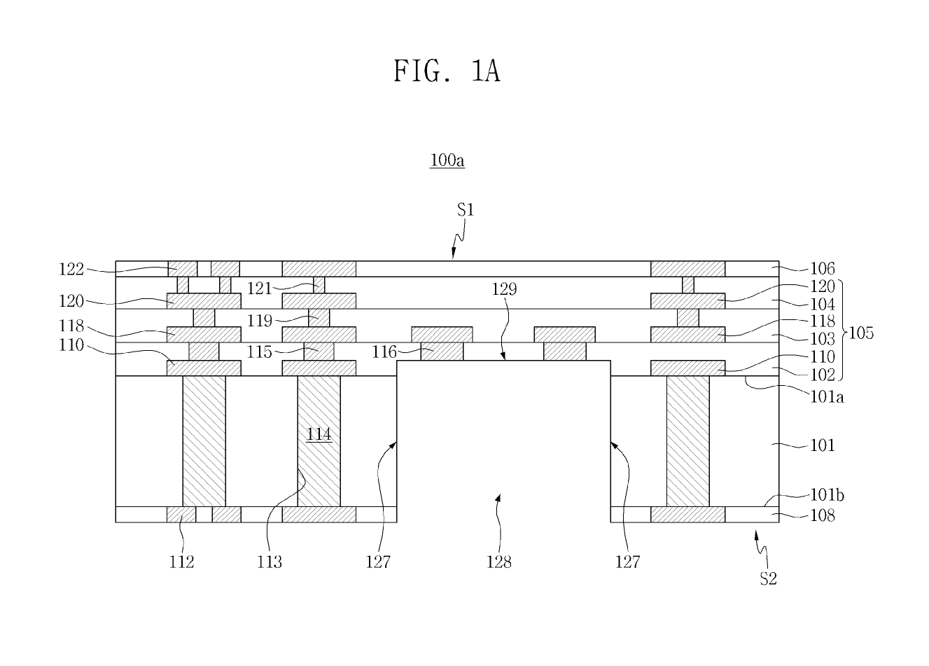

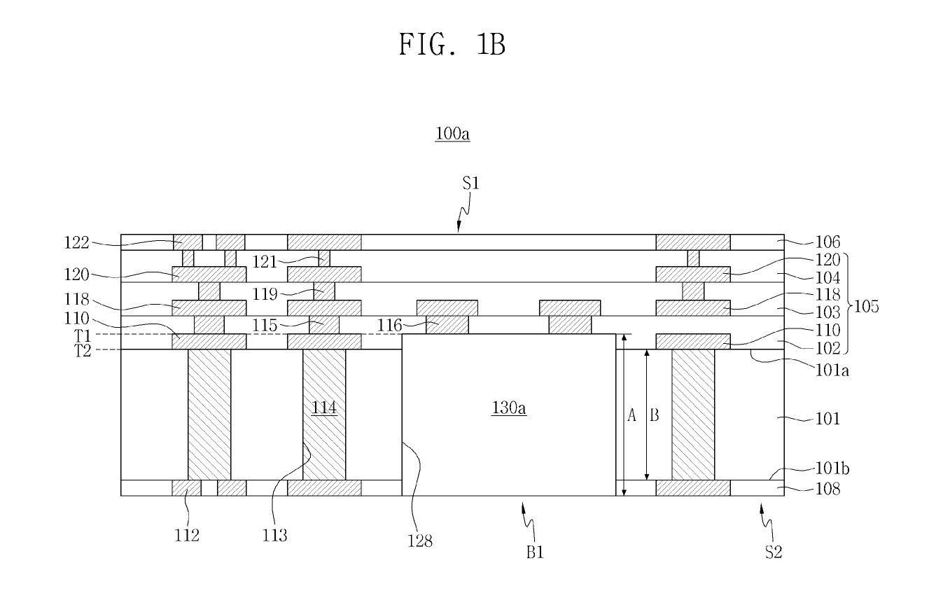

FIGS. 1A and 1B are cross-sectional views illustrating a package substrate in accordance with an exemplary embodiment of the present general inventive concept.

Referring to FIGS. 1A and 1B, a package substrate 100a may include a core layer 101 and a build-up layer 105 formed on the core layer 101.

The package substrate 100a may be a printed circuit board (PCB).

The core layer 101 may include a core top surface 101a and a core bottom surface 101b, and the core bottom surface 101b may include a board connecting area S2 electrically connected to an external board (not illustrated). The core layer 101 may further include through-holes 113 formed thereinside, and through-electrodes 114 formed in the through-holes 113 and electrically connecting the core top surface 101a and the core bottom surface 101b. The through-holes 113 may be formed using a laser drill process, but are not limited thereto.

The build-up layer 105 may be a stacked structure in which a plurality of interconnection layers 110, 118, and 120 and a plurality of insulating layers 102, 103, and 104 are alternately stacked on the core top surface 101a, and may include a chip mounting area 51 on a top surface of the build-up layer 105. The build-up layer 105 may further include a plurality of vias 115, 119, and 121 electrically connecting the plurality of interconnection layers 110, 118, and 120. The plurality of interconnection layers 110, 118, and 120 may be formed by a method of electroplating or chemical plating, but is not limited thereto.

The core layer 101 may include a material having a lower thermal expansion coefficient and a higher elastic coefficient than the plurality of insulating layers 102, 103, and 104. For example, the core layer 101 may include a copper clad laminate (CCL), glass, or a ceramic, but is not limited thereto.

The plurality of insulating layers 102, 103, and 104 may include a material having a higher thermal expansion coefficient and a lower elastic coefficient than the core layer 101. For example, the plurality of insulating layers 102, 103, and 104 may include a pre-preg or an epoxy resin, but is not limited thereto. In order to suppress a warpage phenomenon of the package substrate 100a, it is desirable to form the plurality of insulating layers 102, 103, and 104 as thin as possible.

The package substrate 100a in accordance with an exemplary embodiment of the present general inventive concept may further include first and second connecting terminals 122 and 112 on both surfaces thereof, and first and second solder resist layers 106 and 108 protecting the first and second connecting terminals 122 and 112. The package substrate 100a may be a solder mask defined (SMD) type substrate in which center parts of the first and second connecting terminals 122 and 112 are exposed by the first and second solder resist layers 106 and 108, or a non-solder mask defined (NSMD) type substrate in which the entire top surfaces of the first and second connecting terminals 122 and 112 are exposed.

The first and second connecting terminals 122 and 112 may be formed in a land or pad shape. The first connecting terminals 122 may be formed on a top surface of the build-up layer 105 including the chip mounting area S1, and the second connecting terminals 112 may be formed on the core bottom surface 101b including the board connecting area S2. The first connecting terminals 122 may be electrically connected to the second connecting terminals 112 through the plurality of interconnection layers 110, 118, and 120, and the plurality of vias 115, 119, and 121 and through-electrodes 114. A ground voltage and a power voltage may be applied to the plurality of interconnection layers 110, 118, and 120. The plurality of interconnection layers 110, 118, and 120, the plurality of vias 115, 119, and 121, and the plurality of connecting terminals 122 and 112 may each include a metal, such as Cu, Au, Ag, Pt, Al, and Ni, or an alloy thereof, but are not limited thereto.

According to an exemplary embodiment of the present general inventive concept, the core layer 101 may include a cavity 128 defined by recessed sidewalls 127 extending upward from the core bottom surface 101b and a recessed surface 129, and a device 130a mounted in the cavity 128.

The cavity 128 may be formed at or near an opposite side to the chip mounting area S1. For example, the cavity 128 may be formed by partially removing the core layer 101 using a machining method after manufacturing substantial parts of the package substrate 100a.

The device 130a may be a passive device, such as a capacitor, an inductor, or a resistor, but is not limited thereto. The device 130a may have device connecting terminals 116 on a top surface thereof. That is, the device connecting terminals 116 may be formed on the recessed surface 129 of the cavity 128, and electrically connect the package substrate 100a and the device 130a. The device connecting terminals 116 may be formed in a land or pad shape.

As described above, when the cavity 128 is processed after manufacturing the substantial parts of the package substrate 100a, parts of the plurality of interconnection layers 110, 118, and 120 or the plurality of vias 115, 119, and 121 may be exposed by the processing of the cavity 128. In FIG. 1A, a first via 115 among the plurality of vias 115, 119, and 121 may be exposed and provided as the device connecting terminal 116.

Accordingly, since an interconnection or via exposed to the recessed surface 129 of the cavity 128 among the plurality of interconnection layers 110, 118, and 120 or the plurality of vias 115, 119, and 121 is used as the device connecting terminal 116 with no additional process, manufacturing costs and processing time may be reduced.

A cross-section of the device connecting terminal 116 and the recessed surface 129 of the cavity 128 may configure substantially the same plane by the processing of the cavity 128. The device 130a may be connected to the recessed surface 129 of the cavity 128 by a surface mounting method using a solder ball, a solder bump, and etc.

Referring to FIG. 1B, the second connecting terminal 112 electrically connecting the package substrate 100a to the external board is not formed on a bottom surface B1 of the device 130a. Accordingly, the device 130a may have an increased thickness to further occupy an area in which the second connecting terminal 112 would be otherwise formed. As such, a device with a large capacity may be implemented.

A plurality of cavities 128 may be formed in a single package substrate 100a, and a plurality of devices 130a may be mounted in each of the plurality of cavities 128.

Referring to FIG. 1B, a top surface T1 of the device 130a mounted in the cavity 128 may be located at a higher level than the core top surface 101a or T2, and the bottom surface B1 of the device 130a may be located at the same level as a bottom surface of the package substrate 100a. For example, the top surface T1 of the device 130a may be located at the same level as a top surface of a first interconnection layer 110 among the plurality of interconnection layers. Accordingly, the device 130a may have a thickness A greater than a thickness B of the core layer 101.

In the package substrate 100a in accordance with an exemplary embodiment of the present general inventive concept, the core layer 101 having a low thermal expansion coefficient and a high elastic coefficient may be disposed at a lower part of the package substrate 100a at which a board connector is formed, and the build-up layer 105 having a high thermal expansion coefficient and low elastic coefficient compared to the core layer 101 may be disposed at an upper part of the package substrate 100a at which a semiconductor chip is mounted. Accordingly, since the upper part and the lower part of the package substrate 100a may be formed of materials having different thermal expansion coefficients and elastic coefficients from each other, asymmetric structure of the package substrate 100a may be implemented to suppress warpage of the package substrate 100a. In addition, since interconnection layers and vias are not formed in the core layer 101, a thin package substrate may be implemented.

In addition, since the cavity 128 exposed on the bottom surface of the package substrate 100a is formed in the core layer 101, and the device 130a is mounted in the cavity 128, the thickness, size, and capacity of the device 130a may increase regardless of the thickness of the package substrate 100a. Accordingly, a device with a large capacity may be implemented to secure electrical properties of a package, and flexibility of production of the device may increase.

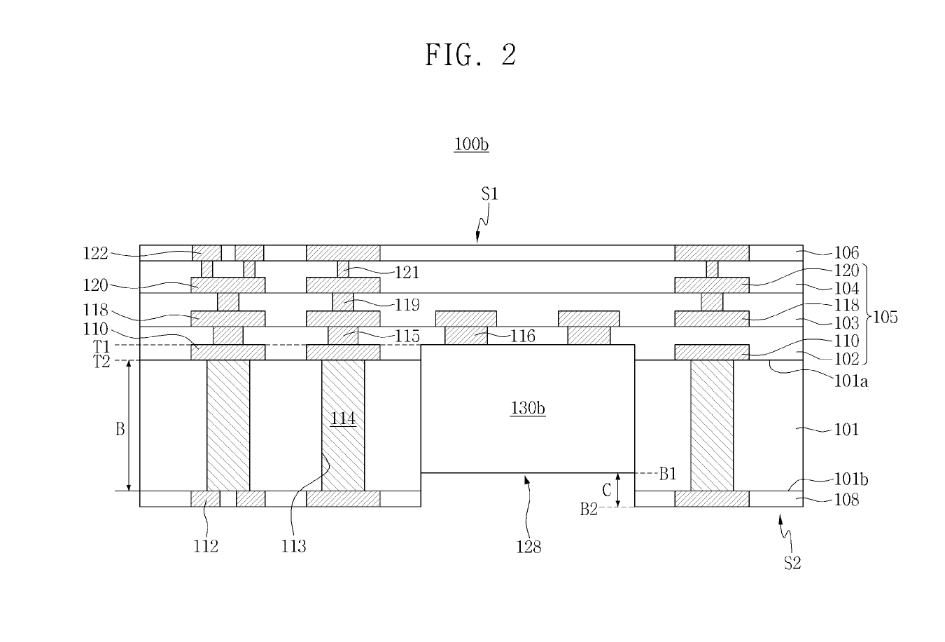

FIGS. 2 through 6B are cross-sectional views illustrating package substrates in accordance with various exemplary embodiments of the present general inventive concept. Hereinafter, descriptions will be focused on modified parts, and duplicate descriptions will be omitted.

Referring to FIG. 2, in a package substrate 100b, a bottom surface B1 of a device 130b mounted in a cavity 128 exposed on a bottom surface B2 of the package substrate 100b may be located at a higher level than the bottom surface B2 of the package substrate 100b. A top surface T1 of the device 130b may be located at a higher level than a core top surface 101a or T2 of a core layer 101. For example, the top surface T1 of the device 130b may be located at the same level as a top surface of a first interconnection layer 110 among a plurality of interconnection layers.

The thickness of the device 130b can be reduced by a thickness C without affecting productivity of the package substrate 100b.

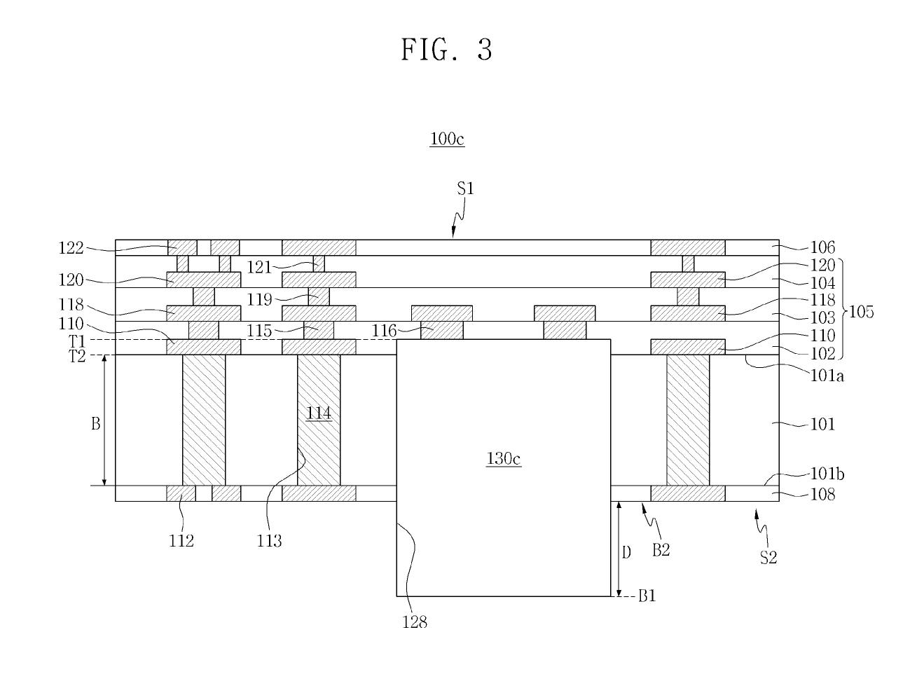

Referring to FIG. 3, in a package substrate 100c, a bottom surface B1 of a device 130c mounted in a cavity 128 exposed on a bottom surface B2 of the package substrate 100c may be located at a lower level than the bottom surface B2 of the package substrate 100c. A top surface T1 of the device 130c may be located at a higher level than a core top surface 101a or T2 of a core layer 101. For example, the top surface T1 of the device 130c may be located at the same level as a top surface of a first interconnection layer 110 among a plurality of interconnection layers.

Since a second connecting terminal 112 electrically connecting the package substrate 100c to an external board (not illustrated) is formed on a core bottom surface 101 b excluding the device 130c, the device 130c may be formed to have the bottom surface B1 protruding out from the bottom surface B2 of the package substrate 100c. The device 130c may be directly electrically connected to the external board.

A distance between the bottom surface B1 of the device 130c and the bottom surface B2 of the package substrate 100c may be smaller than or the same as a joint gap size D between the package substrate 100c and the external board. Accordingly, the device 130c can have a maximum thickness same as a sum of the thickness of the core layer 101, the thickness of the first interconnection layer 110, the thickness of a second solder resist layer 108, and the joint gap size D, resulting in a large capacity.

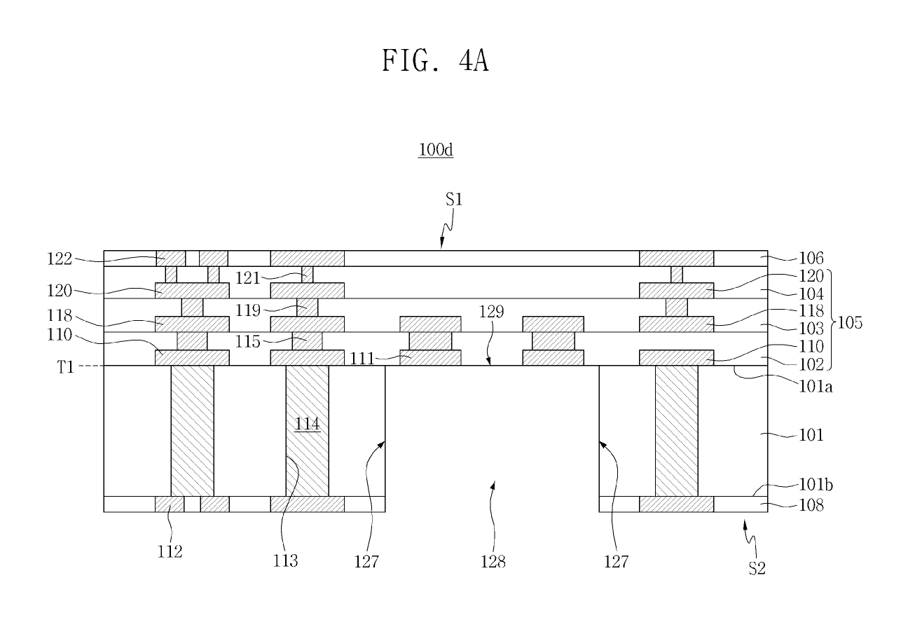

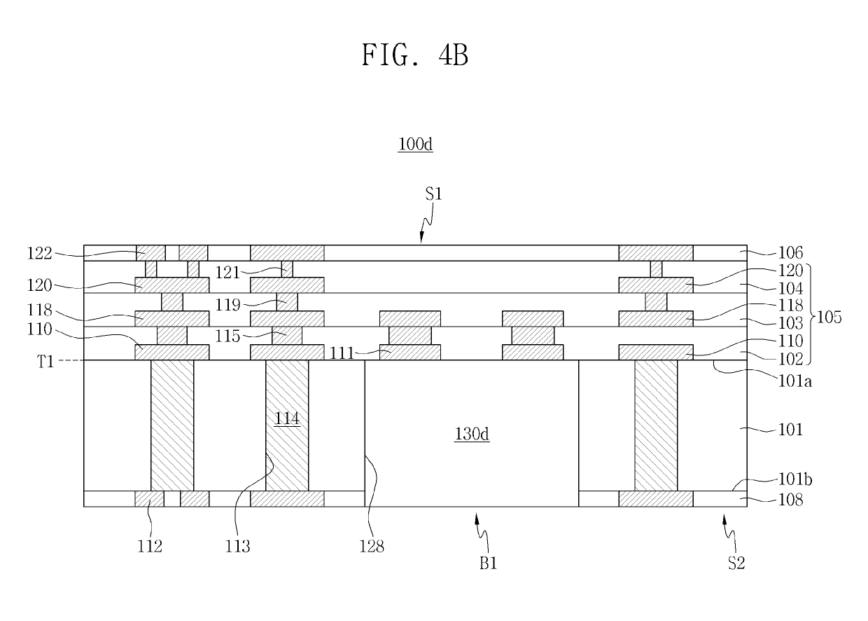

Referring to FIGS. 4A and 4B, in a package substrate 100d, a top surface T1 of a device 130d mounted in a cavity 128 exposed on a bottom surface of the package substrate 100d may be located at the same level as a core top surface 101a of a core layer 101. A bottom surface B1 of the device 130d may be located at the same level as a bottom surface of the package substrate 100d. In addition, although not illustrated in FIGS. 4A and 4B, the bottom surface B1 of the device 130d may be located at a different level from the bottom surface of the package substrate 100d.

The device 130d may include device connecting terminals 111 formed from a plurality of interconnection layers in the package substrate 100d, on the top surface T1 thereof. In addition, a first interconnection layer 110 exposed to a recessed surface 129 of the cavity 128 among the plurality of interconnection layers may be provided as the device connecting terminals 111.

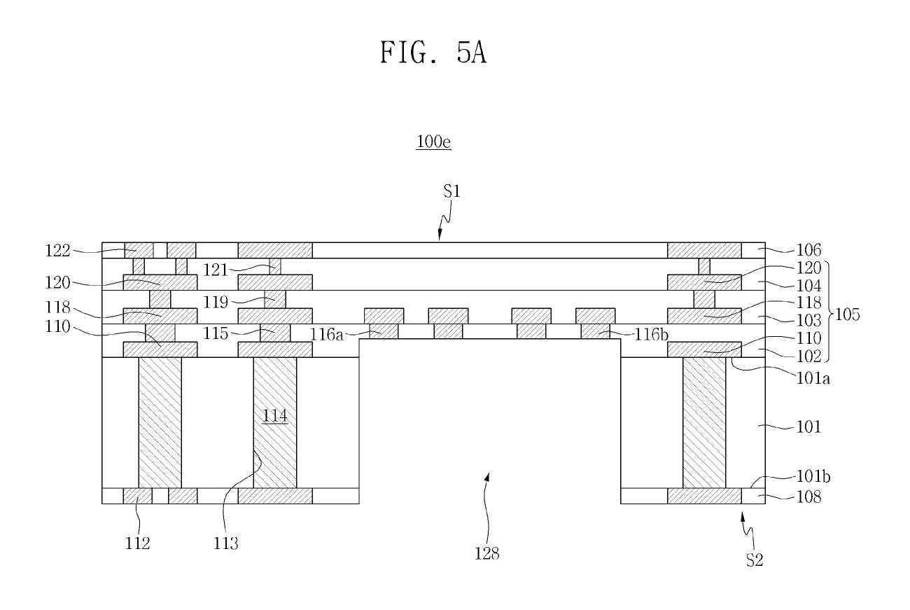

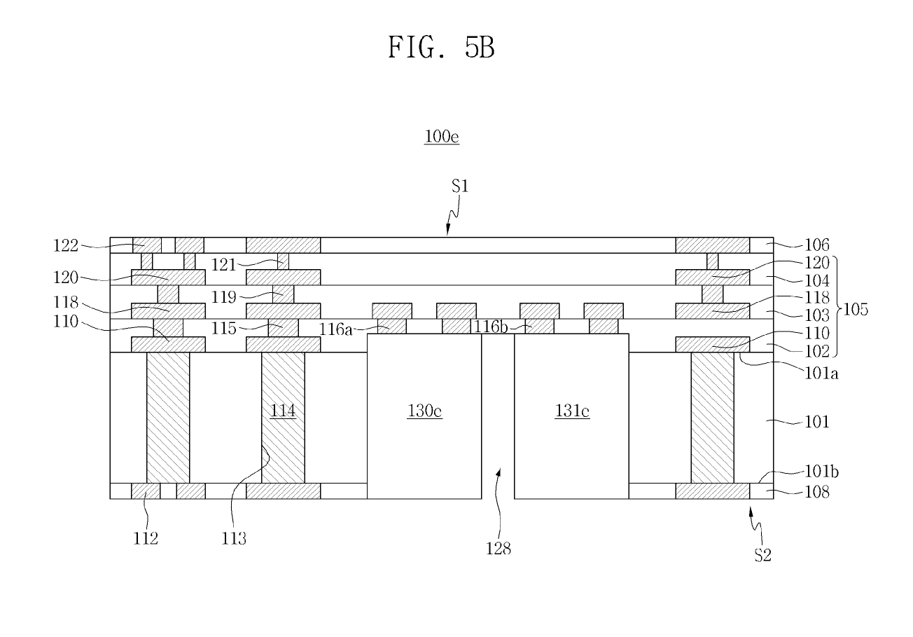

Referring to FIGS. 5A and 5B, in a package substrate 100e in accordance with an exemplary embodiment of the present general inventive concept, two devices 130e and 131e may be mounted respectively in a single cavity 128 formed at or near an opposite side to a chip mounting area S1 of the package substrate 100e.

The devices 130e and 131e, as illustrated in FIG. 5B, may be mounted to be laterally adjacent to each other in the cavity 128. In addition, although not illustrated, the devices 130e and 131e may be vertically stacked in the cavity 128. The devices 130e and 131e may be the same or different. The devices 130e and 131e may respectively have corresponding device connecting terminals 116a and 116b on the top surfaces thereof.

The top surfaces of the devices 130e and 131e, respectively, may be located at a higher level than a core top surface 101a of a core layer 101. Bottom surfaces of the devices 130e and 131 e may be located at the same level as a bottom surface of the package substrate 100e, or at a different level from the bottom surface of the package substrate 100e. Although the top surface and the bottom surface of the device 130e are located at the same levels as the top surface and the bottom surface of the device 131e, respectively, in FIG. 5B, the device 130e may have the surfaces located at different levels with respect to the corresponding surfaces of the device 131e.

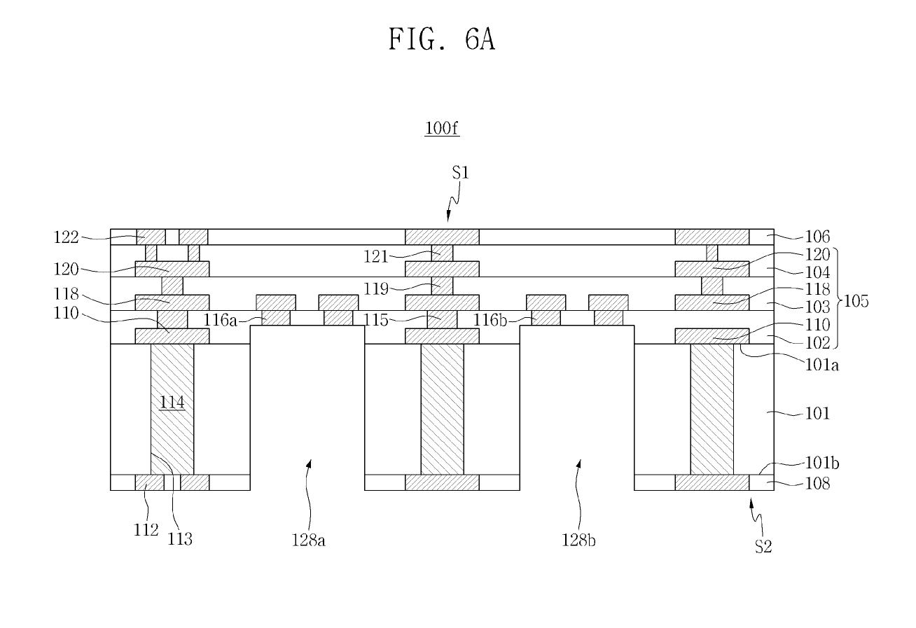

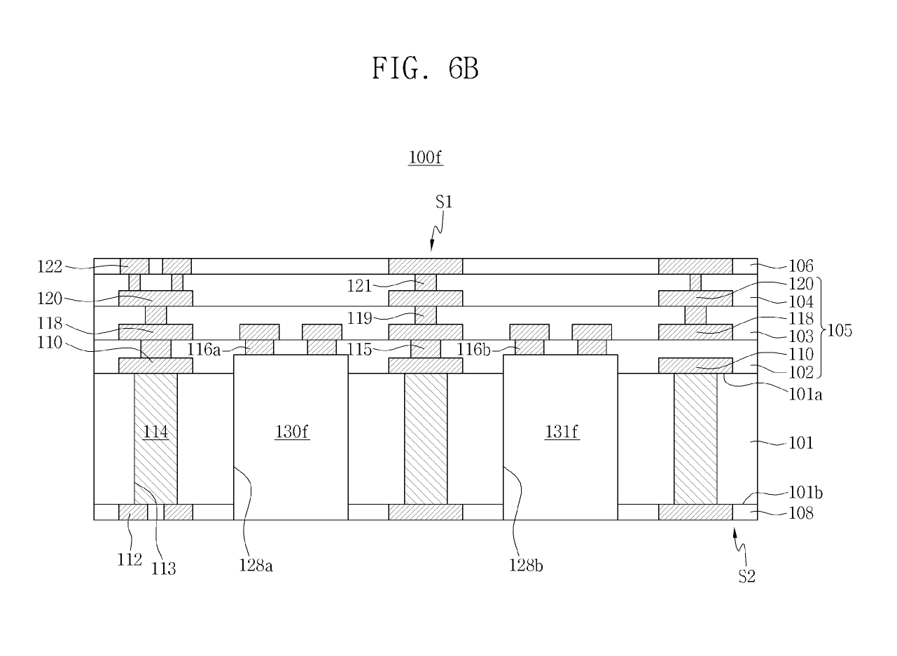

Referring to FIGS. 6A and 6B, a package substrate 100f in accordance with an exemplary embodiment of the present general inventive concept may include two devices 130f and 131f mounted in two cavities 128a and 128b formed at or near an opposite side to a chip mounting area S1 of the package substrate 100f. The devices 130f and 131f may be mounted in different cavities 128a and 128b, respectively, and may have corresponding device connecting terminals 116a and 116b on top surfaces thereof.

The devices 130f and 131f may have respective top surfaces located at the same level. For example, the top surfaces of the devices 130f and 131f may be located at a higher level than a core top surface 101a of the core layer 101. The devices 130f and 131f may have bottom surfaces located at the same level. Bottom surfaces of the devices 130f and 131f may be located at the same level as or a different level from a bottom surface of the package substrate 100f.

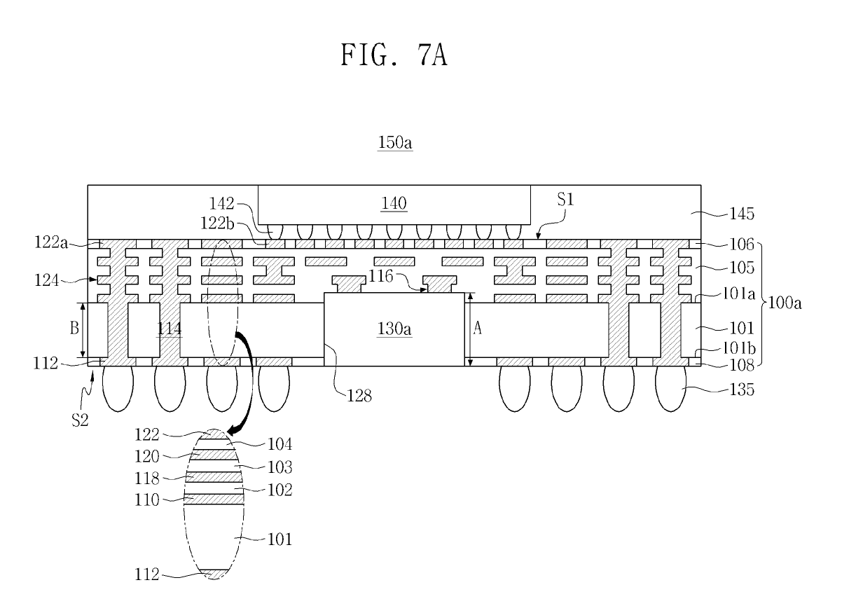

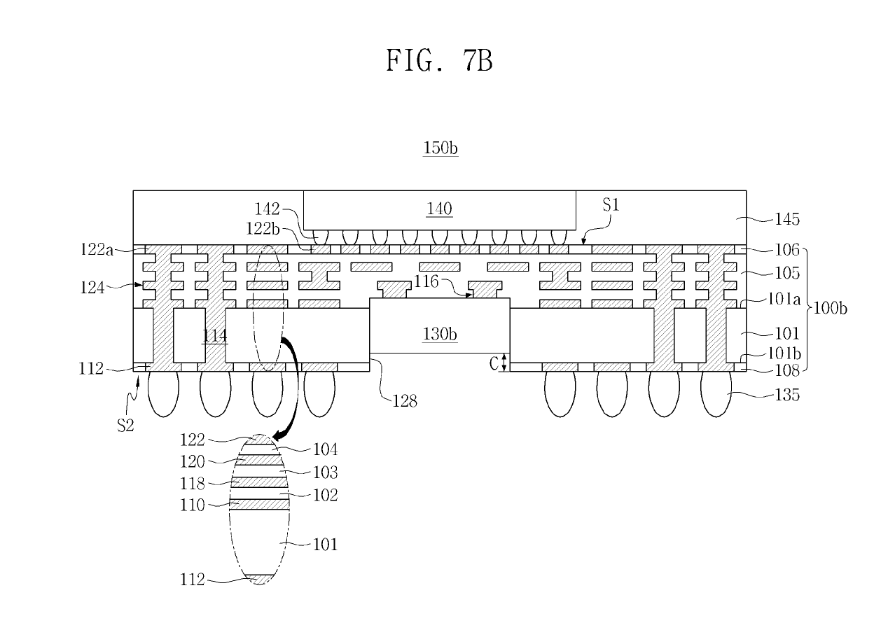

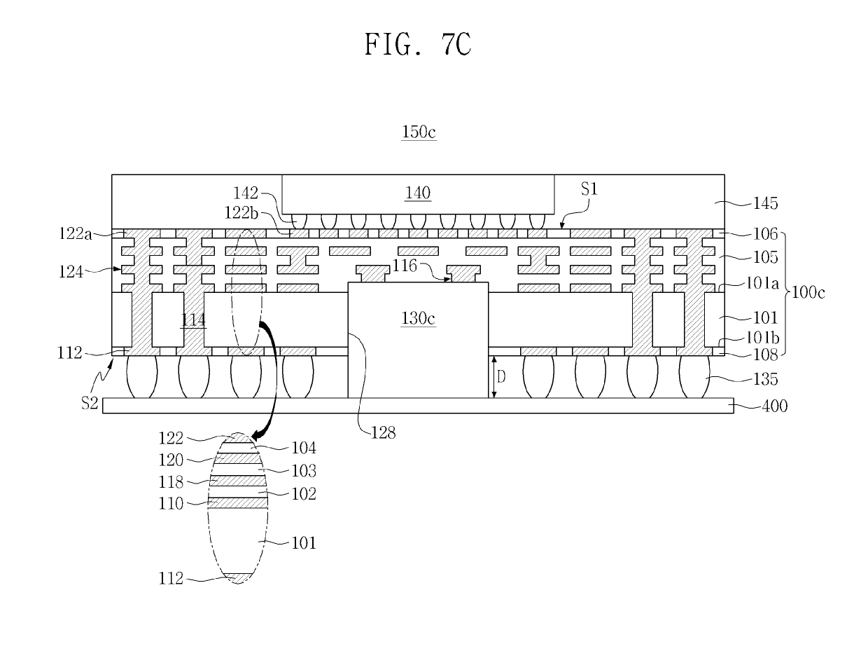

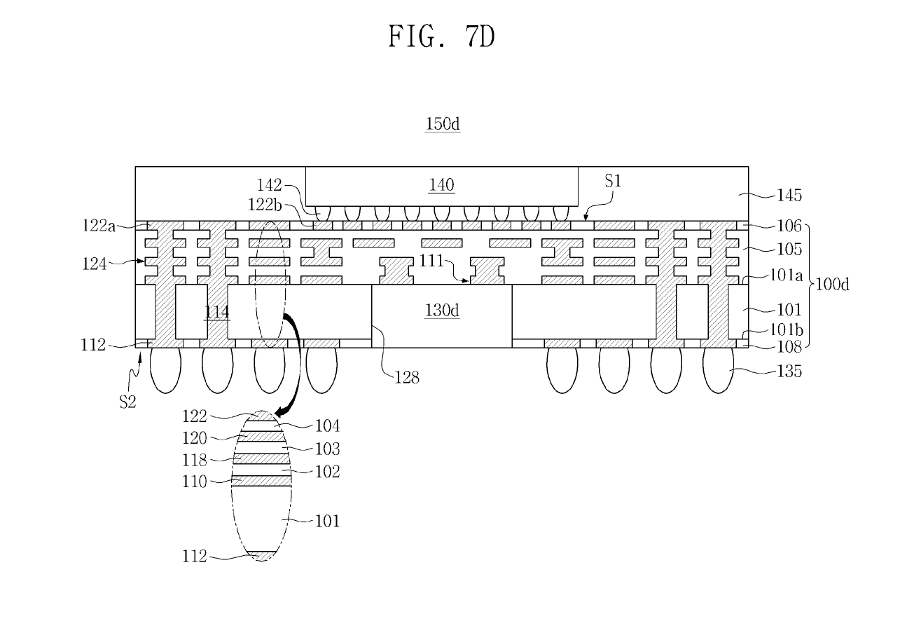

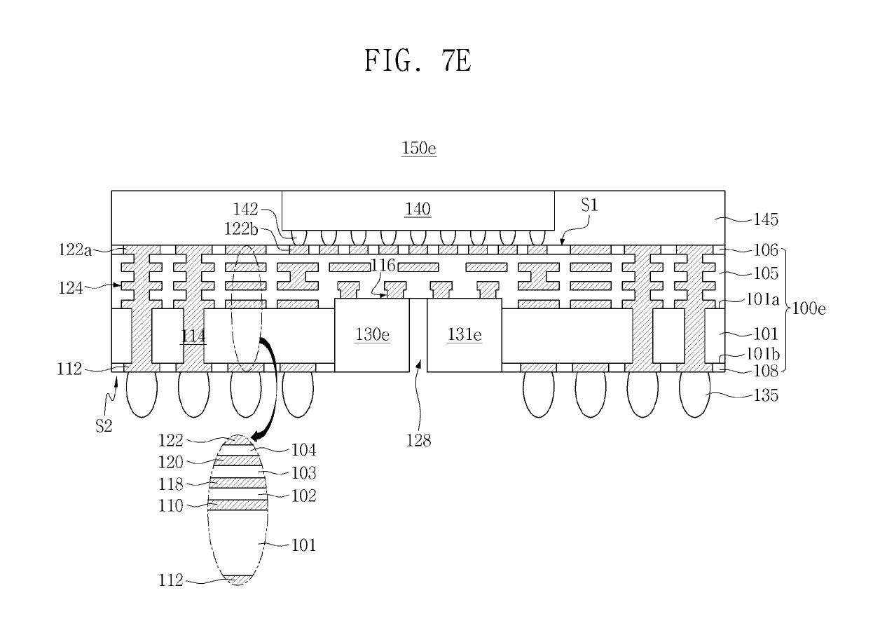

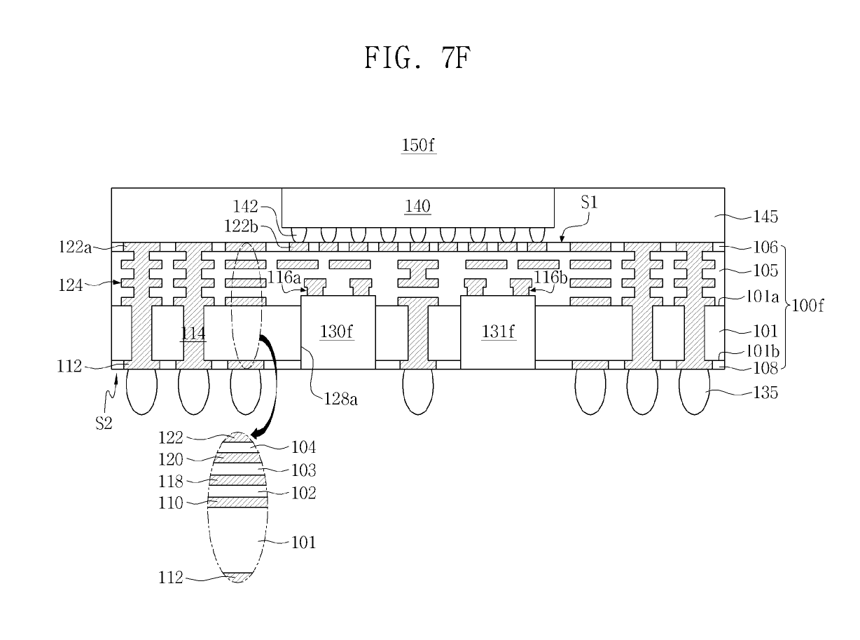

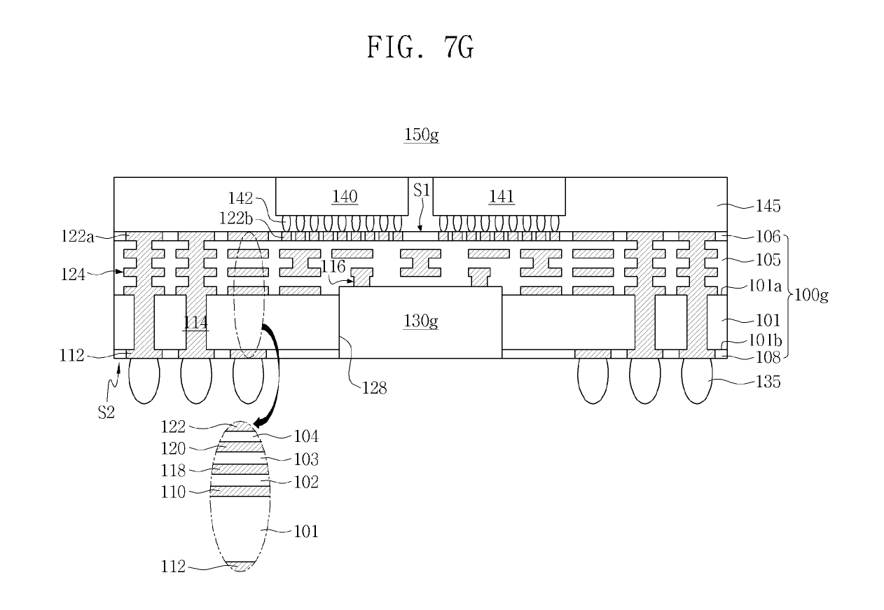

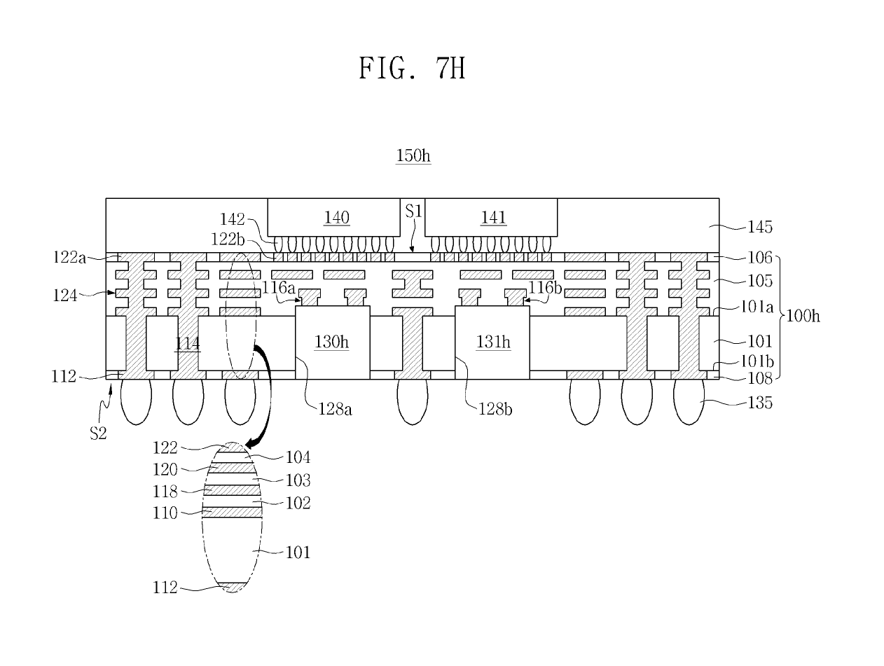

FIG. 7A is a cross-sectional view illustrating a semiconductor package in accordance with an exemplary embodiment of the present general inventive concept.

Referring to FIG. 7A, a semiconductor package 150a may include a package substrate 100a, a semiconductor chip 140 mounted on a chip mounting area S1 of the package substrate 100a, and a board connector 135 formed on board connecting area S2 of the package substrate 100a.

The package substrate 100a may include a core layer 101 having a core top surface 101a and a core bottom surface 101b which includes a board connecting area S2, a build-up layer 105 having a stacked structure in which a plurality of interconnection layers 124 or 110, 118, and 120 and a plurality of insulating layers 102, 103, and 104 are alternately stacked on the core top surface 101a and including the chip mounting area S1 on a top surface of the build-up layer 105, a cavity 128 formed in the core layer 101, and a device 130a mounted in the cavity 128.

The package substrate 100a may further include first and second connecting terminals 122 and 112 formed in both surfaces thereof, and first and second solder resist layers 106 and 108 protecting the first and second connecting terminals 122 and 112. The first connecting terminals 122 may include package connecting terminals 122a formed on a top surface of the build-up layer 105 and electrically connected to another semiconductor package (not illustrated), and chip connecting terminals 122b electrically connected to the semiconductor chip 140. The second connecting terminals 112 may be formed on the core bottom surface 101b and electrically connected to an external board through the board connector 135. The first and second connecting terminals 122 and 112, respectively, may be formed in a land or pad shape.

The semiconductor chip 140 may include a logic device, such as a microprocessor, a microcontroller, or an application processor (AP). The semiconductor chip 140 may be a system on chip (SOC) in which various kinds of semiconductor devices are included in a single semiconductor chip. The semiconductor chip 140 may be connected to the package substrate 100a using a flip chip method. For example, the semiconductor chip 140 may be a flip chip package (FCP) in which an active surface having chip pads formed thereon is disposed to be opposite to the chip mounting area S1 of the package substrate 100a, and then directly connected to the chip connecting terminals 122b of the package substrate 100a using conductive chip bumps 142 attached to the chip pads. The chip bumps 142 may include a solder material or a metal, such as Au, Ag, Pt, Al, Cu, and Ni, but are not limited thereto.

The core layer 101 may further include through-holes 113 formed thereinside, and through-electrodes 114 formed in the through-holes 113 and electrically connecting the core top surface 101a and the core bottom surface 101b. The first connecting terminals 122, which include the package connecting terminals 122a and the chip connecting terminals 122b, may be electrically connected to the second connecting terminals 112 through the plurality of interconnection layers 124 and through-electrodes 114. The core layer 101 may include a material having a lower thermal expansion coefficient and a higher elastic coefficient than the plurality of insulating layers 102, 103, and 104. For example, the core layer 101 may include a copper clad laminate (CCL), glass, or a ceramic, but is not limited thereto, and the plurality of insulating layers 102, 103, and 104 may include a pre-preg or an epoxy resin, but is not limited thereto.

The cavity 128 exposed on a bottom surface of the package substrate 100a may be defined by recessed sidewalls 127 extending upward from the core bottom surface 101b, and a recessed surface 129 located at a higher level than or the same level as the core top surface 101a, as illustrated in FIG. 1A. The cavity 128 may be formed at or near an opposite side to the chip mounting area S1. For example, the cavity 128 may be formed by partially removing the core layer 101 using a machining method after manufacturing substantial parts of the package substrate 100a.

The device 130a may be a passive device, such as a capacitor, an inductor, or a resistor. Device connecting terminals 116 electrically connecting the device 130a to the package substrate 100a may be formed by exposing parts of the plurality of vias 115, 119, and 121 connecting the plurality of interconnection layers 124 or the plurality of interconnection layers 124 from each other by processing of the cavity 128. The device connecting terminals 116 may be formed in a land or pad shape. The device 130a may be connected to the device connecting terminals 116 by a surface mounting method using a solder ball, a solder bump, and etc.

The top surface of the device 130a may be located at a higher level than the core top surface 101a, and a bottom surface of the device 130a may be located at the same level as the bottom surface of the package substrate 100a. The device 130a may have a thickness A greater than the thickness B of the core layer 101.

In FIGS. 7A and 7B, the second connecting terminal 112 and the board connector 135 may be formed on a core bottom surface 101b excluding the device 130a. Accordingly, the device 130a may have an increased thickness to occupy an area in which the board connector 135 is not formed, thereby implementing a large capacity. Although not illustrated in FIGS. 7A and 7B, the second connecting terminal 112 and the board connector 135 may also be formed on the bottom surface of the device 130a.

FIGS. 7B through 7H are cross-sectional views illustrating semiconductor packages in accordance with various exemplary embodiments of the present general inventive concept. Hereinafter, descriptions will be focused on modified parts, and duplicate descriptions will be omitted.

Referring to FIG. 7B, in a semiconductor package 150b, a top surface of a device 130b mounted in a cavity 128 exposed on a bottom surface of a package substrate 100b may be located at a higher level than a core top surface 101a of a core layer 101, and a bottom surface of the device 130b may be located at a higher level than the bottom surface of the package substrate 100b. For example, the top surface of a device 130b may be located at the same level as a top surface of a first interconnection layer 110 among a plurality of interconnection layers.

A thickness of the device 130b may be reduced by a thickness C without affecting productivity of the package substrate 100b.

Referring to FIG. 7C, in a semiconductor package 150c, a bottom surface of a device 130c mounted in a cavity 128 exposed on a bottom surface of a package substrate 100c may be located at a lower level than the bottom surface of the package substrate 100c.

A top surface of the device 130c may be located at a higher level than a core top surface 101a of the core layer 101. For example, the top surface of the device 130c may be located at the same level as a top surface of a first interconnection layer 110 among a plurality of interconnection layers.

Since a second connecting terminal 112 and a board connector 135 electrically connecting the package substrate 100c to an external board 400 are formed on a core bottom surface 101b excluding the device 130c, the device 130c may be formed to have the bottom surface thereof protruding higher than the bottom surface of the package substrate 100c. The device 130c may be directly electrically connected to the external board 400.

A distance between the bottom surface of the device 130c and the bottom surface of the package substrate 100c may be smaller than or the same as a joint gap size D between the package substrate 100c and the external board 400. Accordingly, the thickness of the device 130c may be smaller than or the same as the sum of the thickness of the core layer 101, the thickness of the first interconnection layer 110, the thickness of a second solder resist layer 108, and the joint gap size D.

Referring to FIG. 7D, in a semiconductor package 150d, a top surface of a device 130d mounted in a cavity 128 exposed in a bottom surface of a package substrate 100d may be located at the same level as a core top surface 101a of a core layer, and a bottom surface of the device 130d may be located at the same level as the bottom surface of the package substrate 100d. Although not illustrated in FIG. 7D, the bottom surface of the device 130d may be located at a different level from the bottom surface of the package substrate 100d.

Referring to FIG. 7E, a semiconductor package 150e may include a semiconductor chip 140 mounted on a chip mounting area S1 of a package substrate 100e, and two devices 130e and 131e mounted in a single cavity 128 formed at or near an opposite side to the semiconductor chip 140 of the package substrate 100e.

The devices 130e and 131e may be mounted to be laterally adjacent to each other in the cavity 128, as illustrated in FIG. 7E. In addition, although not illustrated, the devices 130e and 131e may be vertically stacked in the cavity 128. The devices 130e and 131e may be the same or different. The devices 130e and 131e may have corresponding device connecting terminals 116a and 116b on top surfaces thereof. The device connecting terminals 116a and 116b may be formed from a plurality of interconnection layers 124.

The top surfaces of the devices 130e and 131e may be located at a higher level than a core top surface 101a of a core layer 101. Bottom surfaces of the devices 130e and 131e, as illustrated in FIG. 7E, may be located at the same level as a bottom surface of the package substrate 100e, or at different levels from the bottom surface of the package substrate 100e.

Referring to FIG. 7F, a semiconductor package 150f may include a semiconductor chip 140 mounted on a chip mounting area S1 of a package substrate 100f, and two devices 130f and 131f mounted in two cavities 128a and 128b formed at or near an opposite side to the semiconductor chip 140 of the package substrate 100f.

The devices 130f and 131f may be mounted in different cavities 128a and 128b, and may have corresponding device connecting terminals 116a and 116b on top surfaces thereof.

The devices 130f and 131f may have the top surfaces at the same level. For example, a top surface of each of the devices 130f and 131f may be located at a higher level than a core top surface 101a of a core layer 101. The devices 130f and 131f may have bottom surfaces at the same level. A bottom surface of each of the devices 130f and 131f may be located at the same level as a bottom surface of the package substrate 100f or at a different level from the bottom surface of the package substrate 100f.

Referring to FIG. 7G, a semiconductor package 150g may include two semiconductor chips 140 and 141 mounted on a chip mounting area S1 of a package substrate 100g, and a device 130g mounted in a single cavity 128 formed opposite to the two semiconductor chips 140 and 141 of the package substrate 100g.

Although not illustrated in FIG. 7G, two devices may be mounted in a single cavity 128. In this case, the devices may be laterally arranged adjacent to each other, or vertically stacked.

Referring to FIG. 7H, a semiconductor package 150h may include two semiconductor chips 140 and 141 mounted on a chip mounting area S1 of a package substrate 100h, and two devices 130h and 131h respectively mounted in two cavities 128a and 128b formed corresponding to the two semiconductor chips 140 and 141 of the package substrate 100h. Each of the devices 130h and 131h may be aligned with the corresponding semiconductor chips 140 and 141.

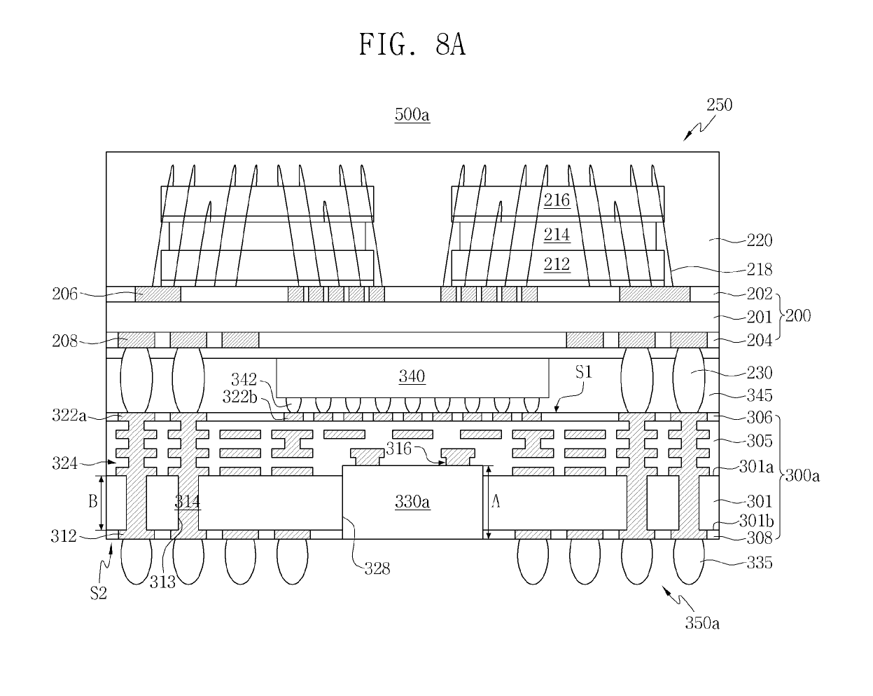

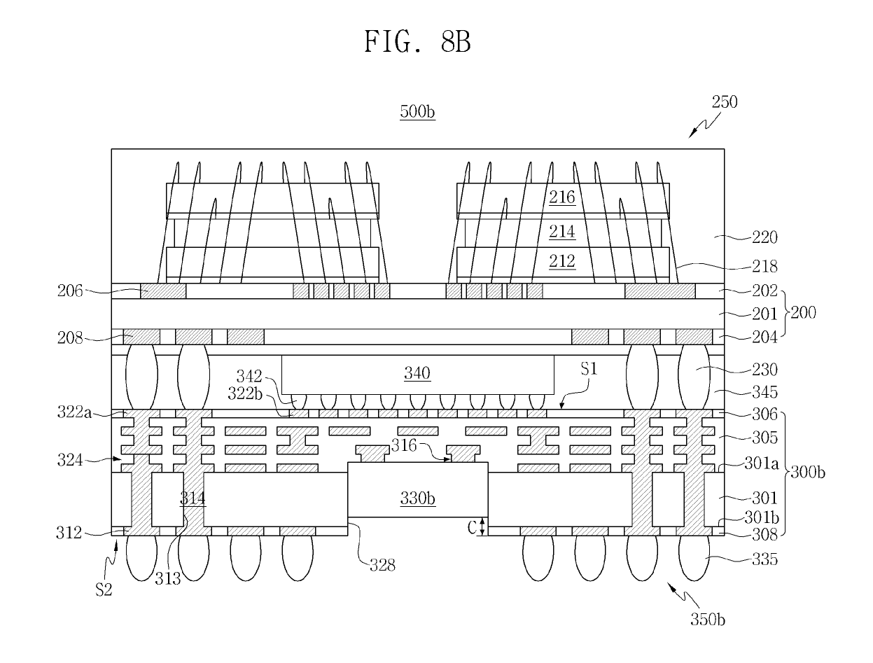

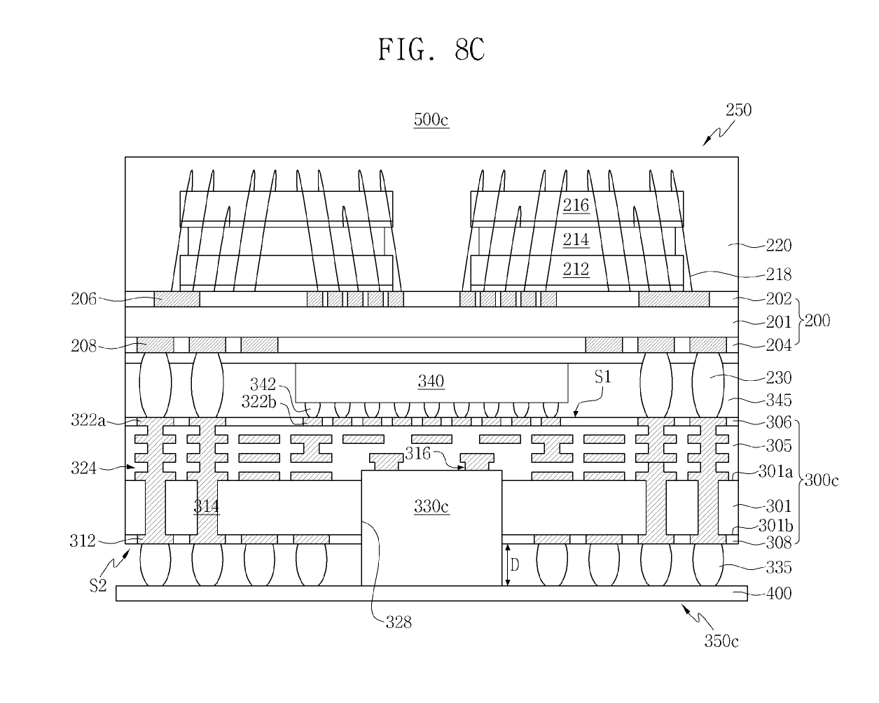

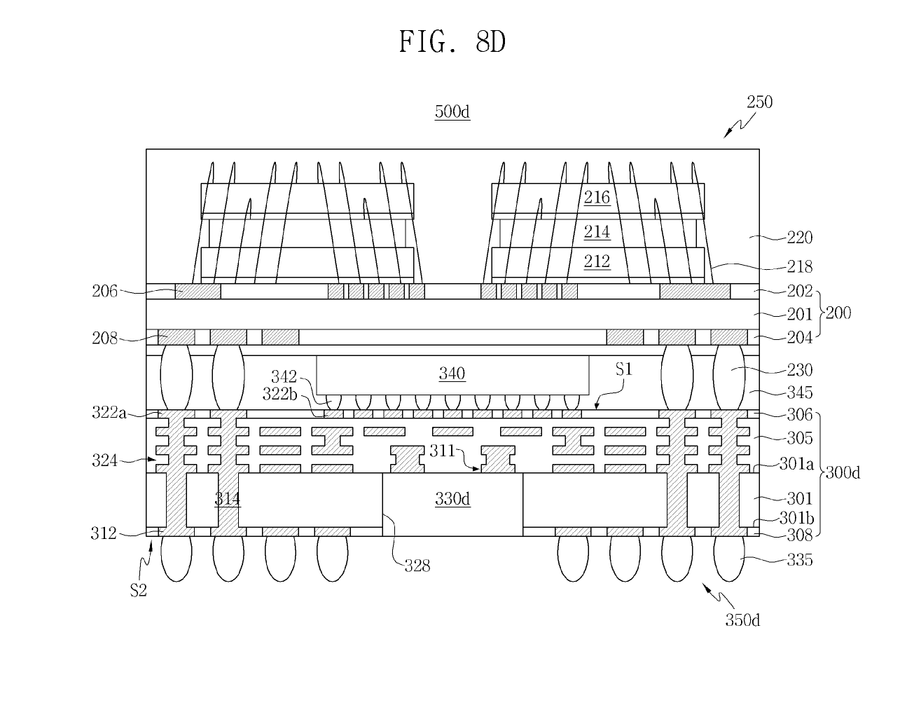

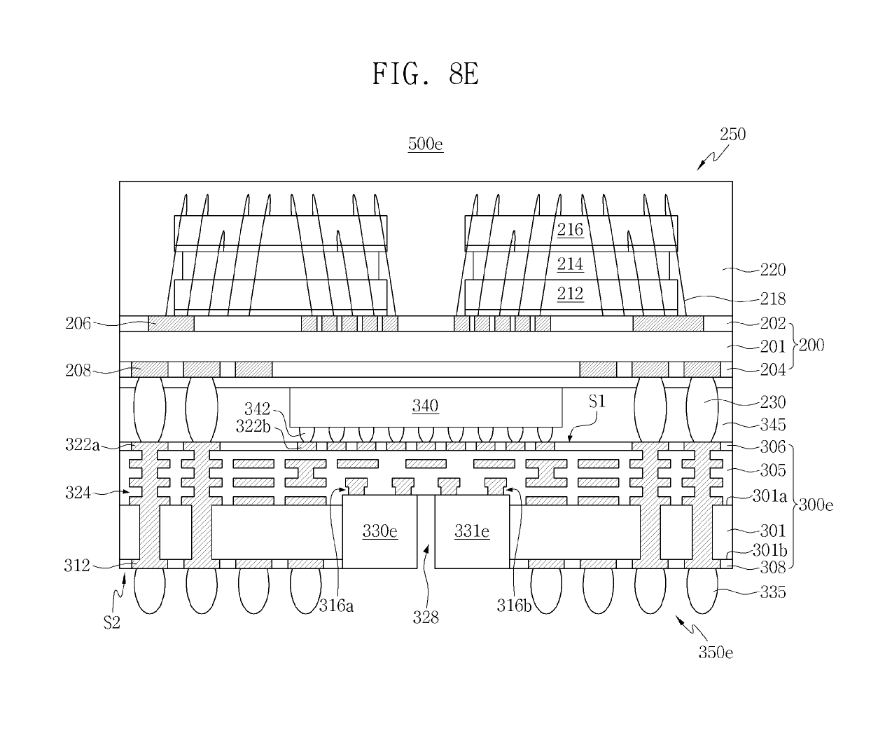

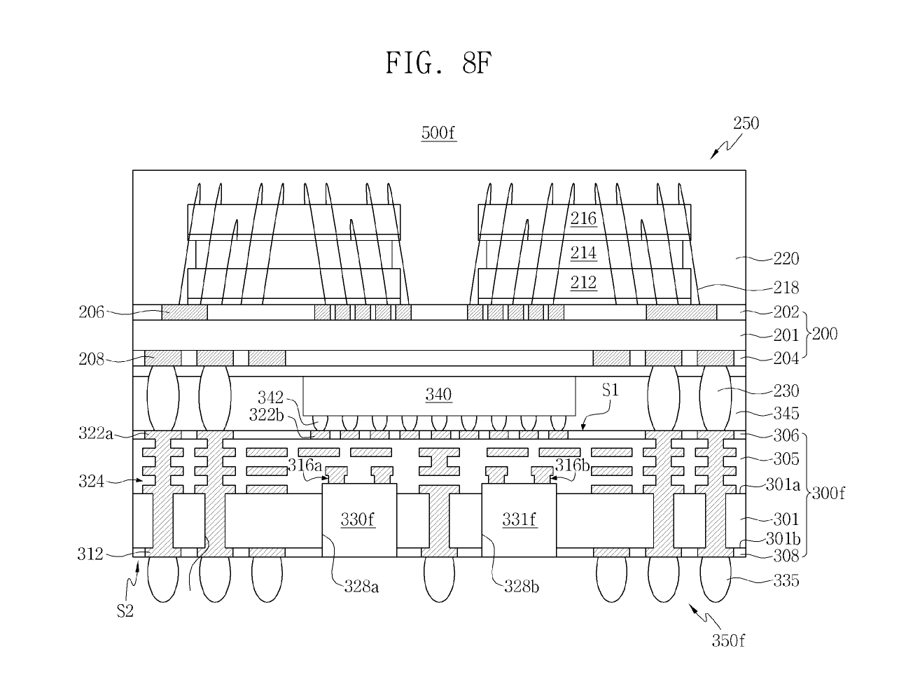

FIG. 8A is a cross-sectional view illustrating a stacked semiconductor package in accordance with an exemplary embodiment of the present general inventive concept.

Referring to FIG. 8A, a stacked semiconductor package 500a may include a lower semiconductor package 350a, an upper semiconductor package 250, an inter-package connector 230, and a board connector 335.

The stacked semiconductor package 500a may have a package on package (POP) structure in which the upper semiconductor package 250 is stacked on the lower semiconductor package 350a. The lower semiconductor package 350a and the upper semiconductor package 250 may be packages of which packaging and an electrical test are independently completed.

The lower semiconductor package 350a may include a lower package substrate 300a, and a lower semiconductor chip 340 mounted on a chip mounting area S1 of the lower package substrate 300a.

The lower package substrate 300a may be a printed circuit board (PCB) in which a plurality of lower interconnection layers 324 are formed. A ground voltage and a power voltage may be applied to the plurality of lower interconnection layers 324.

The lower package substrate 300a may include a lower core layer 301 having a core top surface 301a and a bottom surface 301b that includes a board connecting area S2, a build-up layer 305 having a stacked structure in which a plurality of lower interconnection layers 324 and a plurality of insulating layers are alternately stacked on the core top surface 301a and having the chip mounting area S1 on a top surface of the build-up layer 305, a cavity 328 formed on the lower core layer 301, and a device 330a mounted in the cavity 328.

The lower package substrate 300a may further include first lower connecting terminals 322a and 322b formed on a top surface thereof and protected by a first lower solder resist layer 306, and second lower connecting terminals 312 formed on a bottom surface thereof and protected by a second lower solder resist layer 308. The first lower connecting terminals 322a and 322b may be formed on a top surface of the build-up layer 305, and may include package connecting terminals 322a electrically connected to the upper semiconductor package 250 through the inter-package connector 230, and chip connecting terminals 322b electrically connected to the lower semiconductor chip 340. The second lower connecting terminals 312 may be formed on the core bottom surface 301b, and electrically connected to an external board through the board connector 335. The first lower connecting terminals 322a and 322b and the second lower connecting terminals 312 may be formed in a land or pad shape.

The lower semiconductor chip 340 may include a logic device, such as a microprocessor, a microcontroller, or an application processor (AP), but is not limited thereto. The lower semiconductor chip 340 may be an SOC in which various kinds of semiconductor devices are included in a single semiconductor chip. The lower semiconductor chip 340 may be connected to the lower package substrate 300a using a flip-chip method. For example, the lower semiconductor chip 340 may be a flip-chip package (FCP) formed in such a way that an active surface in which chip pads are formed is arranged opposite to the chip mounting area 51 of the lower package substrate 300a, and then directly connected to the chip connecting terminals 322b of the lower package substrate 300a using conductive chip bumps 342 attached to the chip pads. The chip bumps 342 may include a solder material or a metal, such as Au, Ag, Pt, Al, Cu, and Ni, but are not limited thereto.

The lower core layer 301 may further include through-holes 313 formed thereinside, and through-electrodes 314 formed in the through-holes 313 and electrically connecting the core top surface 301a and the core bottom surface 301b. The first lower connecting terminals 322a and 322b may be electrically connected to the second lower connecting terminals 312 through the plurality of lower interconnection layers 324 and through-electrodes 314. The lower core layer 301 may include a material having a lower thermal expansion coefficient and a higher elastic coefficient than the plurality of insulating layers. For example, the lower core layer 301 may include a copper clad laminate (CCL), glass, or a ceramic, but is not limited thereto, and the plurality of insulating layers may include a pre-preg or an epoxy resin, but is not limited thereto.

The cavity 328 exposed on a bottom surface of the lower package substrate 300a may be defined by sidewalls extending upward from the core bottom surface 301b, and a recessed surface located at a higher level than or at the same level as the core top surface 301a. The cavity 328 may be formed at or near an opposite side to the chip mounting area S1. For example, the cavity 328 may be formed by partially removing the lower core layer 301 using a machining method after manufacturing substantial parts of the lower package substrate 300a.

The device 330a may be a passive device, such as a capacitor, an inductor, or a resistor. Parts of the plurality of lower interconnection layers 324 or a plurality of lower vias connecting the plurality of lower interconnection layers 324 from each other may be exposed by processing of the cavity 328, to form device connecting terminals 316 electrically connecting the device 330a to the lower package substrate 300a on the recessed surface 129 of the cavity 128. The device connecting terminals 316 may be formed in a land or pad shape. The device 330a may be connected to the device connecting terminals 316 by a surface mounting method using a solder material such as a solder ball a solder bump, or a solder paste.

A top surface of the device 330a may be located at a higher level than the core top surface 301 a, and a bottom surface of the device 330a may be located at the same level as the bottom surface of the lower package substrate 300a. The device 330a may have a thickness A greater than a thickness B of the lower core layer 301.

The board connectors 335 electrically connecting the stacked semiconductor package 500a to an external board, such as a semiconductor module board or a system board, may be formed on the second lower connecting terminals 312 of the lower package substrate 300a. The board connectors 335 may be formed of a solder material, such as a solder ball, a solder bump, and a solder paste, or a metal having a spherical, mesa, or pin shape, but are not limited thereto. The board connectors 335 may be arranged in a grid type implementing a ball grid array (BGA) package.

In FIG. 8A, the second lower connecting terminal 312 and the board connector 335 may be formed on the core bottom surface 301b excluding the device 330a. Accordingly, the device 330a can have an increased thickness due to existence of an area in which the board connector 335 is not formed, thereby implementing a large capacity. However, the second lower connecting terminal 312 and the board connector 335 may also be formed on the bottom surface of the device 330a.

The lower semiconductor package 350a may further include a lower molding material 345 formed on the lower package substrate 300a. The lower molding material 345 may be formed to protect electrical connection between the lower semiconductor chip 340 and the lower package substrate 300a, and surround the lower semiconductor chip 340 and the chip bumps 342. In addition, the lower molding material 345 may release stress acting on a top surface of the lower package substrate 300a. The lower molding material 345 may include an epoxy resin or an epoxy mold compound (EMC), but is not limited thereto.

The upper semiconductor package 250 may be vertically stacked on the lower semiconductor package 350a, and may include an upper package substrate 200, and at least one of a plurality of upper semiconductor chips 212, 214, and 216 mounted on the upper package substrate 200. The upper semiconductor package 250 may be a multi-chip package (MCP) in which the plurality of upper semiconductor chips 212, 214, and 216 are vertically stacked. In addition, the upper semiconductor package 250 may have a structure in which a plurality of semiconductor chips is vertically stacked on a plurality of laterally arranged semiconductor chips.

The upper package substrate 200 may be a substrate in which a plurality of upper interconnection layers are formed, and may include a rigid printed circuit board, a flexible printed circuit board, or a rigid-flexible printed circuit board. The upper package substrate 200 may include an upper core layer 201 and upper solder resist layers 202 and 204. A plurality of upper interconnection layers (not illustrated) may be formed in the upper core layer 201 of the upper package substrate 200. A ground voltage and a power voltage may be applied to the plurality of upper interconnection layers.

First upper connecting terminals 206 isolated from each other by a first upper solder resist layer 202 may be formed on a top surface of the upper package substrate 200. Second upper connecting terminals 208 isolated from each other by a second upper solder resist layer 204 may be formed on a bottom surface of the upper package substrate 200. The first upper connecting terminals 206 may be electrically connected to the second upper connecting terminals 208 through the upper interconnection layers.

The upper semiconductor chips 212, 214, and 216 may each include a memory device. The upper semiconductor chips 212, 214, and 216 may be connected to the upper package substrate 200 using a wire bonding method or a flip-chip method. For example, chip pads formed on an active surface of the upper semiconductor chips 212, 214, or 216 may be electrically connected to the first upper connecting terminals 206 of the upper package substrate 200 through wires 218. Although the upper semiconductor chips 212, 214, and 216 are illustrated as being connected to the upper package substrate 200 using the wire bonding method in FIG. 8A, the upper semiconductor chips 212, 214, and 216 may be directly connected to the upper package substrate 200 using the flip-chip method.

The upper semiconductor package 250 may further include an upper molding material 220 formed on the upper package substrate 200, and surrounding and protecting the active surface of the upper semiconductor chips 212, 214, and 216 and the wires 218. The upper molding material 220 may include an epoxy resin or an EMC, but is not limited thereto.

The inter-package connectors 230 may be disposed between the first lower connecting terminals 322a of the lower package substrate 300a and the second upper connecting terminals 208 of the upper package substrate 200, and may electrically connect the lower semiconductor package 350a and the upper semiconductor package 250. The inter-package connector 230 may include a lower connector formed on the first lower connecting terminal 322a of the lower package substrate 300a through a via hole passing through the lower molding material 345, and an upper connector formed on the second upper connecting terminal 208 of the upper package substrate 200. The inter-package connector 230 may include a solder material or a metal bump, such as Au, Cu, or Ni, but is not limited thereto.

FIGS. 8B through 8F are cross-sectional views illustrating stacked semiconductor packages in accordance with various exemplary embodiments of the present general inventive concept.

Referring to FIG. 8B, in a stacked semiconductor package 500b, a top surface of a device 330b mounted in a cavity 328 exposed on a bottom surface of a lower package substrate 300b may be located at a higher level than a core top surface 301a of a lower core layer 301, and a bottom surface of the device 330b may be located at a higher level than the bottom surface of a lower package substrate 300b. The thickness of the device 330b may be reduced by a thickness C without affecting productivity of the lower package substrate 300b.

Referring to FIG. 8C, in a stacked semiconductor package 500c , a top surface of a device 330c mounted in a cavity 328 exposed on a bottom surface of a lower package substrate 300c may be located at a lower level than the bottom surface of a lower package substrate 300c. The top surface of a device 330c may be located at a higher level than a core top surface 301a of a core layer 301.

Second lower connecting terminals 312 electrically connected to first lower connecting terminals 322a and 322b and device connecting terminals 316 of the lower package substrate 300c through a plurality of lower interconnection layers 324, and board connectors 335 electrically connecting the second lower connecting terminals 312 to an external board 400, may be formed on a core bottom surface 301b excluding the device 330c. Accordingly, the device 330c may be formed to have a bottom surface protruding higher than the bottom surface of the package substrate 300c. The device 330c may be directly electrically connected to the external board 400.

A distance between the bottom surface of the device 330c and the bottom surface of the lower package substrate 300c may be smaller than or the same as a joint gap size D between the lower package substrate 300c and the external board 400. Accordingly, the device 330c may have a maximum thickness same as a sum of a total thickness of the core layer 301, the lower interconnection layer, and a second solder resist layer 308, plus the joint gap size D.

Referring to FIG. 8D, in a stacked semiconductor package 500d a top surface of a device 330d mounted in a cavity 328 exposed on a bottom surface of a lower package substrate 300d may be located at the same level as a core top surface 301 a of a core layer 301, and a bottom surface of the device 330d may be located at the same level as the bottom surface of a lower package substrate 300d. Although not illustrated in FIG. 8D, the bottom surface of the device 330d may be located at a different level from the bottom surface of the lower package substrate 300d.

Referring to FIG. 8E, a stacked semiconductor package 500e may include a lower semiconductor chip 340 mounted on a chip mounting area S1 of a lower package substrate 300e, and two devices 330e and 331 e mounted in a single cavity 328 formed at or near an opposite side to the lower semiconductor chip 340 of the lower package substrate 300e.

The devices 330e and 331e may be mounted to be laterally adjacent to each other in the cavity 328. In addition, although not illustrated in FIG. 8E, the devices 330e and 331e may be vertically stacked in the cavity 328. The devices 330e and 331e may be the same or different. The devices 330e and 331e may have corresponding device connecting terminals 316a and 316b on top surfaces thereof. The device connecting terminals 316a and 316b may be formed from a plurality of lower interconnection layers 324.

The top surfaces of the devices 330e and 331e may be located at a higher level than a core top surface 301a of a core layer 301. Bottom surfaces of the devices 330e and 331e, as illustrated in FIG. 8E, may be located at the same level as a bottom surface of the lower package substrate 300e, or at different levels from the bottom surface of the lower package substrate 300e.

Referring to FIG. 8F, a stacked semiconductor package 500f may include a lower semiconductor chip 340 mounted on a chip mounting area S1 of a lower package substrate 300f, and two devices 330f and 331f mounted respectively in two cavities 328a and 328b formed at or near an opposite side to the lower semiconductor chip 340 of the lower package substrate 300f.

The devices 330f and 331f may be mounted in different cavities 328a and 328b, respectively, and may have device connecting terminals 316a and 316b on corresponding top surfaces thereof.

The devices 330f and 331f may have the top surfaces at the same level. For example, a top surface of each of the devices 330f and 331f may be located at a higher level than a core top surface 301a of a core layer 301. The devices 330f and 331f may have bottom surfaces at the same level. A bottom surface of each of the devices 330f and 331f may be located at the same level as or at a different level from the bottom surface of the lower package substrate 300f.

Although not illustrated in FIG. 8F, the stacked semiconductor package 500f may include a plurality of lower semiconductor chips mounted on a chip mounting area S1 of the lower package substrate 300f, and a plurality of devices mounted in a cavity formed at or near an opposite side to the plurality of lower semiconductor chips of the lower package substrate. The plurality of devices may be mounted in a single cavity, or different cavities.

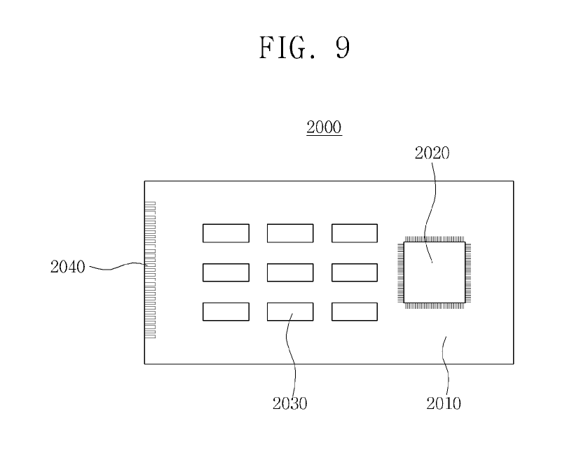

FIG. 9 is a diagram schematically showing a module in accordance with an exemplary embodiment of the present general inventive concept.

Referring to FIG. 9, a module 2000 may include semiconductor packages and/or stacked semiconductor packages 2030 mounted on a module substrate 2010.

The module 2000 may further include a microprocessor 2020 mounted on the module substrate 2010. Input/output terminals 2040 may be arranged on at least one side of the module substrate 2010. The semiconductor packages and/or stacked semiconductor packages 2030 may be mounted on the module substrate 2010 using a flip-chip method.

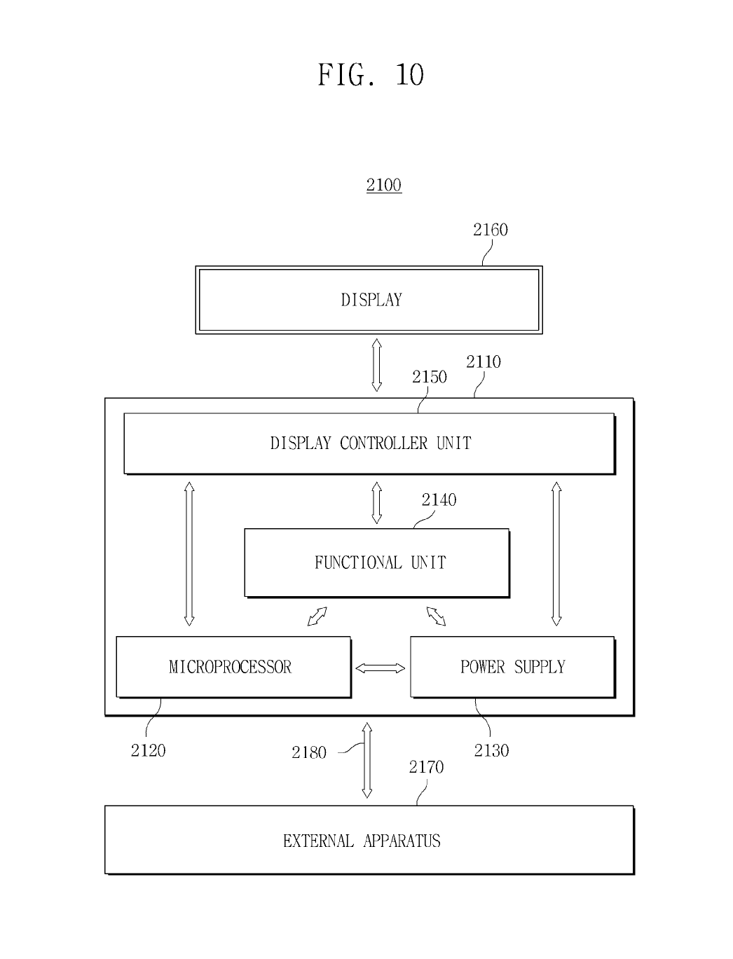

FIG. 10 is a block diagram schematically showing an electronic system in accordance with an exemplary embodiment of the present general inventive concept.

Referring to FIG. 10, various semiconductor packages and/or stacked semiconductor packages may be applied in an electronic system 2100.

The electronic system 2100 may include a body 2110, a microprocessor unit 2120, a power supply unit 2130, a function unit 2140, and/or a display controller unit 2150.

The body 2110 may include a system board or motherboard having a printed circuit board (PCB), or the like. The microprocessor unit 2120, the power supply unit 2130, the function unit 2140, and the display controller unit 2150 may be installed or mounted on the body 2110. A display unit 2160 may be arranged inside or outside of the body 2110. For example, the display unit 2160 may be disposed on a surface of the body 2110 to display an image processed by the display controller unit 2150. The power supply unit 2130 may receive a constant voltage from an external battery, but is not limited thereto, divide the voltage into various levels of voltages, and supply those voltages to different components including the microprocessor unit 2120, the function unit 2140, and the display controller unit 2150. The microprocessor unit 2120 may receive a voltage from the power supply unit 2130 to control the function unit 2140 and the display unit 2160. The function unit 2140 may perform various functions. For example, if the electronic system 2100 is a mobile electronic apparatus such as a mobile phone, the function unit 2140 may have several components performing wireless communication such as dialing, video output to the display unit 2160 through communication with an external apparatus 2170, and sound output to a speaker, and if a camera is installed, the function unit 2140 may function as an image processor.

In an exemplary embodiment of the present general inventive concept, when the electronic system 2100 is connected to a memory card, or the like, in order to expand capacity, the function unit 2140 may be a memory card controller. The function unit 2140 may exchange signals with the external apparatus 2170 through a wired or wireless communication unit 2180. In addition, when the electronic system 2100 needs an external memory, such as a universal serial bus (USB), in order to expand functionality, the function unit 2140 may function as an interface controller.

The microprocessor unit 2120 or the function unit 2140 may include at least one of the semiconductor packages and/or stacked semiconductor packages described in accordance with various exemplary embodiments of the present general inventive concept.

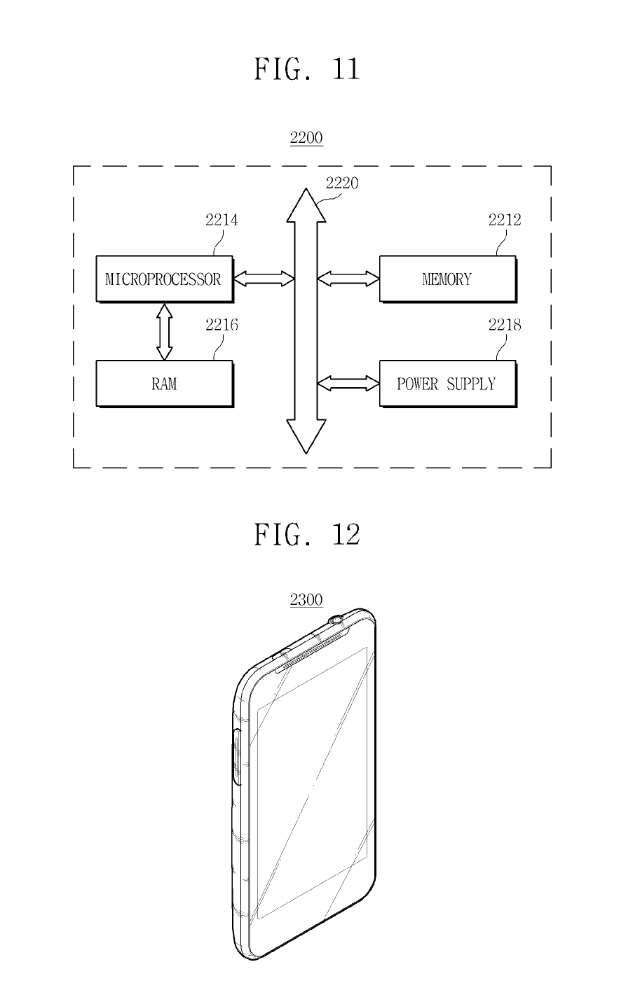

FIG. 11 is a block diagram schematically illustrating an electronic system including a module in accordance with an exemplary embodiment of the present general inventive concept.

Referring to FIG. 11, an electronic system 2200 may include a semiconductor package and/or stacked semiconductor packages. The electronic system 2200 may be used to fabricate a mobile apparatus or a computer. For example, the electronic system 2200 may include a memory system 2212, a microprocessor 2214, a random access memory (RAM) 2216, and a user interface 2218 performing data communication using a bus 2220. The microprocessor 2214 may program and control the electronic system 2200. The RAM 2216 may be used as an operation memory of the microprocessor 2214. For example, the microprocessor 2214 or the RAM 2216 may include a semiconductor package and/or stacked semiconductor packages in accordance with embodiments of the present general inventive concept. The microprocessor 2214, the RAM 2216, and/or other components may be assembled in a single package. The user interface 2218 may be used to input data to or output data from the electronic system 2200. The memory system 2212 may store codes used for operating the microprocessor 2214, data processed by the microprocessor 2214, or external input data. The memory 2212 may include a controller and a memory.

FIG. 12 is a diagram schematically showing a mobile wireless phone 2300 using the electronic system 2200 of FIG. 11 in accordance with an exemplary embodiment of the present general inventive concept. In addition, the electronic system 2200 of FIG. 11 may be used in a notebook computer, an MPEG-1 Audio Layer 3 (MP3) player, an MP4 player, a navigation apparatus, a solid state disk (SSD), a desktop computer, an automobile, or a home appliance, but is not limited thereto.

According to various exemplary embodiments of the present general inventive concept, by disposing a core layer on a lower part of a package substrate at which a board connector is formed, and a build-up layer on an upper part of the package substrate at which a semiconductor chip is mounted, an asymmetrical package substrate may be implemented, and thereby warpage of the package substrate may be suppressed.

Since interconnection layers and vias are not formed in the core layer, the thickness of the package substrate may be reduced to implement a thin package substrate.

Since a cavity exposed on a bottom surface of the package substrate is formed in the core layer, and a device is mounted in the cavity, the thickness of the device may be formed to be greater than that of the core layer. Accordingly, a device having a high capacity may be implemented to secure electrical characteristics of a package, and flexibility of production of the device may increase.

Although a few embodiments of the present general inventive concept have been shown and described, it will be appreciated by those skilled in the art that changes may be made in these embodiments without departing from the principles and spirit of the present general inventive concept, the scope of which is defined in the appended claims and their equivalents.

What is claimed is:

1. A package substrate, comprising:
a core layer having a core top surface and a core bottom surface, wherein the core bottom surface includes a board connecting area; and
a build-up layer having a stacked structure in which a plurality of interconnection layers and a plurality of insulating layers are alternately stacked on the core top surface, and a chip mounting area on a surface thereof,
wherein the core layer includes:
at least one cavity defined by recess sidewalls extending upward from the core bottom surface, and a recessed surface located at a higher level than or the same level as the core top surface;
at least one device mounted in the at least one cavity; and
through-electrodes electrically connecting the core top surface and the core bottom surface.

2. The package substrate of claim 1, wherein the at least one device is formed thicker than the core layer.

3. The package substrate of claim 1, wherein a bottom surface of the at least one device is located at a lower level than a bottom surface of the package substrate.

4. The package substrate of claim 1, wherein a bottom surface of the at least one device is located at the same level as a bottom surface of the package substrate.

5. The package substrate of claim 1, wherein a bottom surface of the at least one device is located at a higher level than the core bottom surface.

6. The package substrate of claim 1, further comprising:
device connecting terminals located on a top surface of the at least one device and formed from the plurality of interconnection layers.

7. The package substrate of claim 1, wherein the at least one cavity is formed at or near an opposite side to the chip mounting area.

8. The package substrate of claim 1, wherein two or more devices are mounted in a single cavity.

9. The package substrate of claim 1, wherein each device is mounted in a different cavity.

10. The package substrate of claim 1, wherein the core layer includes a material having a lower thermal expansion coefficient and a higher elastic coefficient than the plurality of insulating layers.

11. The package substrate of claim 1, wherein the device is a passive device, such as a capacitor, an inductor, or a resistor.

12. A semiconductor package, comprising:
a package substrate including a core layer having a core top surface and a core bottom surface that has a board connecting area, a build-up layer having a stacked structure in which a plurality of interconnection layers and a plurality of insulating layers are alternately stacked on the core top surface and including a chip mounting area on a surface thereof, at least one cavity defined by recess sidewalls extending upward from the core bottom surface and a recessed surface located at a higher level than or the same level as the core top surface, at least one device mounted in the at least one cavity, and through-electrodes electrically connecting the core top surface and the core bottom surface;
at least one semiconductor chip mounted on the chip mounting area; and
board connectors formed on the board connecting area and electrically connecting the package substrate to an external board.

13. The semiconductor package of claim 12, wherein a bottom surface of the at least one device is located at a lower level than a bottom surface of the package substrate, and a distance between the bottom surface of the device and the bottom surface of the package substrate is smaller than or the same as a joint gap size between the package substrate and the external board.

14. The semiconductor package of claim 12, wherein the board connectors are formed on the core bottom surface excluding the devices.

15. A semiconductor package substrate, comprising:
a core layer having a top surface and a bottom surface;
a build-up layer, disposed on the top surface of the core layer, having interconnection layers connected through vias;
a cavity penetrating from the bottom surface through the top surface of the core layer and recessed within a bottom surface of the build-up layer to house a device thicker than the core layer therein; and
connecting terminals disposed outside of the cavity at the bottom surface of the core layer to connect the device to an external component.

16. The semiconductor package substrate in claim 16, wherein the core layer and the build-up layer are connected by through-electrodes.

17. The semiconductor package substrate in claim 16, wherein the cavity is mounted with at least one other device in addition to the device.

18. The semiconductor package substrate in claim 16, wherein the cavity is formed in the core layer as multiple cavities.

19. The semiconductor package substrate in claim 16, wherein a bottom surface of the device is protruding out from a level corresponding to the bottom surface of the core layer.

20. The semiconductor package substrate in claim 16, wherein the device is electrically connected to the build-up layer through at least one of the interconnection layers and the vias.
